(19) United States
(12) Patent Application Publication
(10) Pub. No.: US 2023/0282779 A1
(43) Pub. Date: Sep. 7, 2023

(54) SEMICONDUCTOR ELEMENT AND METHOD FOR FABRICATING THE SAME

(71) Applicant: InnoLux Corporation, Miao-Li County (TW)

(72) Inventor: Chun-Hui HUANG, Miao-Li County (TW)

(73) Assignee: InnoLux Corporation, Miao-Li County (TW)

(21) Appl. No.: 18/107,486

(22) Filed: Feb. 8, 2023

(30) Foreign Application Priority Data
Mar. 4, 2022 (CN) 202210210108.8

(51) Int. Cl. H01L 33/38; H01L 33/00; H01L 25/075; H01L 33/04; H01L 33/62

(52) U.S. Cl. CPC H01L 33/382; H01L 33/0095; H01L 25/0756; H01L 33/04; H01L 33/62

(57) ABSTRACT

The present disclosure discloses a method for fabricating a semiconductor element. First, a substrate is provided. Next, a semiconductor stack is formed on the substrate. After an ohmic contact layer is formed on the semiconductor stack, an annealing process is carried out on the ohmic contact layer. To be continued, a mesa process is carried out on the semiconductor stack after the annealing process is carried out.

### BACKGROUND OF THE DISCLOSURE

### 1. Field of the Disclosure

The present disclosure relates to a manufacturing method of a semiconductor element, in particular is directed to a manufacturing method of a semiconductor element by stabilizing the quality of an ohmic contact layer.

### 2. Description of the Prior Art

With the development of science and technology and the demands for use, devices using light-emitting diodes (LEDs) are gradually applied in daily life. In order to increase the yield of the light-emitting diode products, the use of the ohmic contact layer has a significant positive effect on improving the current distribution of the light-emitting diode products and improving the light extraction efficiency of the light-emitting diode products. However, it is difficult to maintain the quality of the ohmic contact layer under the current structure and process design of the light emitting diode. Therefore, it is needed to provide an improved structure or an improved process to help stabilize the photoelectric properties of the light emitting diode products.

### SUMMARY OF THE DISCLOSURE

In view of this, it is desirable to maintain the quality of the ohmic contact layer to facilitate the stabilization of the optoelectronic value of the light emitting diode products. For example, a novel manufacturing method of a display device may provide a semiconductor element with an ohmic contact layer of stable quality.

Some embodiments of the present disclosure provide a manufacturing method of a semiconductor element. First, a substrate is provided. Next, a semiconductor stack is formed on the substrate. After an ohmic contact layer is formed on the semiconductor stack, an annealing process is carried out on the ohmic contact layer. To be continued, a mesa process is carried out on the semiconductor stack after the annealing process is carried out.

Some embodiments of the present disclosure further provide a semiconductor element. The semiconductor element includes a first-type semiconductor layer, a quantum well layer, a second-type semiconductor layer, an ohmic contact layer, a first electrode and a second electrode. The first-type semiconductor layer includes a platform and a concave surrounding the platform, wherein the platform and the concave together form a stepped structure. The quantum well layer is disposed on the platform of the first-type semiconductor layer. The second-type semiconductor layer is disposed on the quantum well layer. The ohmic contact layer is disposed on the second type semiconductor layer. The first electrode is electrically connected to the first type semiconductor layer. The second electrode is electrically connected to the ohmic contact layer.

According to the manufacturing method of a semiconductor element of some embodiments of the present disclosure, by carrying out an annealing process on the ohmic contact layer on the semiconductor stack, the quality of the ohmic contact layer may be maintained. In this way, it is beneficial to the stability of the optoelectronic value of the light-emitting diode product, to facilitate the technological progress and innovation of the semiconductor elements.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1, FIG. 2, FIG. 3, FIG. 4, FIG. 5 and FIG. 6 illustrate schematic flowcharts of a first embodiment of a manufacturing method of a semiconductor element 101 according to the present disclosure, and illustrate schematic cross-sectional views of the semiconductor element.

FIG. 1, FIG. 2, FIG. 3A, FIG. 4A, FIG. 5A to FIG. 6A are schematic flowcharts of a second embodiment of a manufacturing method of a semiconductor element according to the present disclosure, and illustrate schematic cross-sectional views of the semiconductor element.

FIG. 7 shows the X-ray diffraction peak patterns of X-ray diffraction analysis (XRD) diffracted at specific angles of the indium tin oxide composition under different temperature conditions.

FIG. 8 illustrates a top-view image of the scanning electron microscope of the semiconductor element of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the electronic device, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not function.

In the following description and in the claims, the terms “include”, “comprise” and “have” are used in an open-ended fashion, and thus should be interpreted to mean “contain, but not limited to”.

When a component or a film layer is referred to as “disposed on another component or another film layer” or “connected to another component or another film layer”, it can mean that the component or film layer is directly disposed on another component or film layer, or directly connected to another component or film layer, or there may be other components or film layers in between. In contrast, when a component is said to be “directly disposed on another component or film” or “directly connected to another component or film”, there is no component or film between the two.

When a structure is referred to as “connected to” or “inter-connected to” another structure in some embodiment of the present disclosure, it can mean that the structure directly contacts another structure, or indirectly contacts another structure, or there may be other structures between the two structures.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

The technical features in different embodiments described in the following may be replaced, recombined, or mixed with one another to constitute another embodiment without departing from the spirit of the present disclosure.

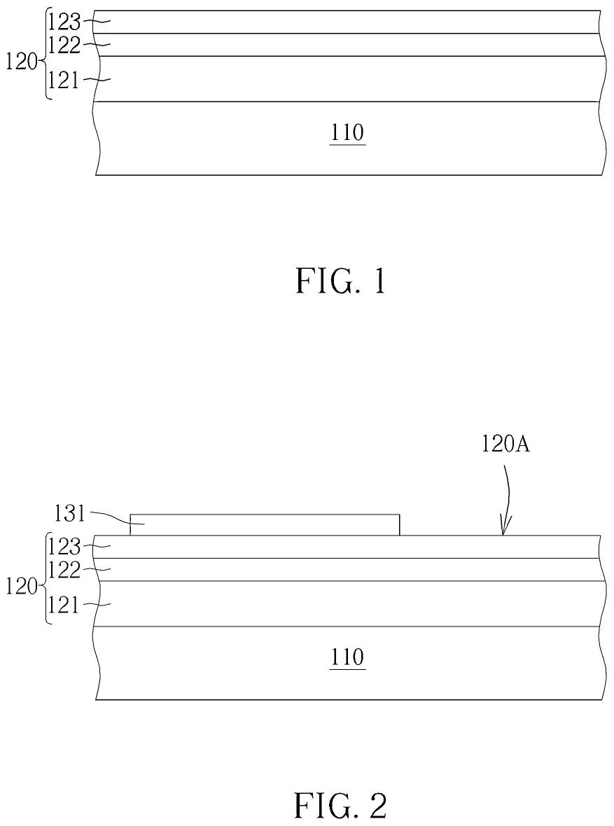

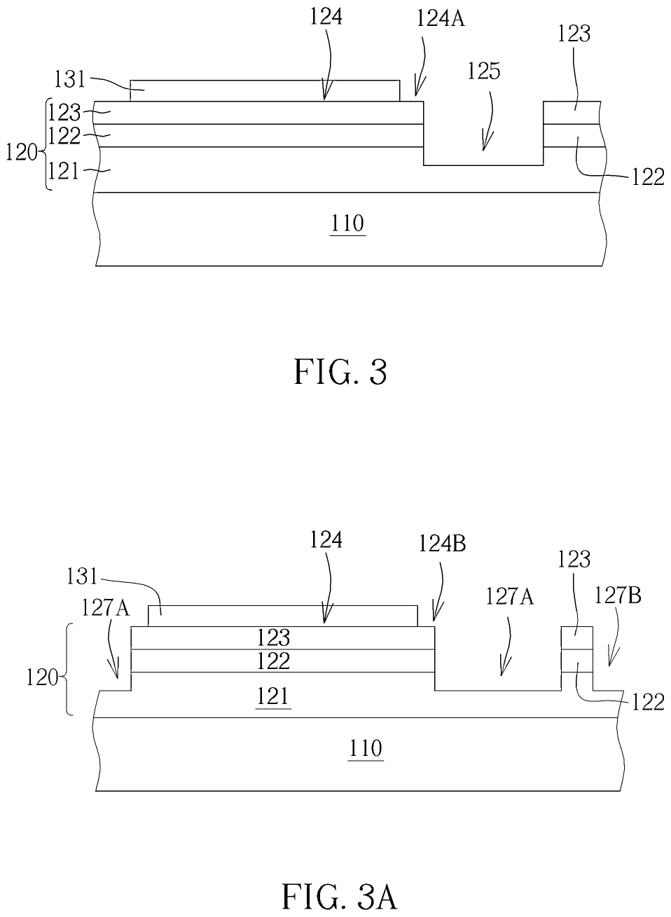

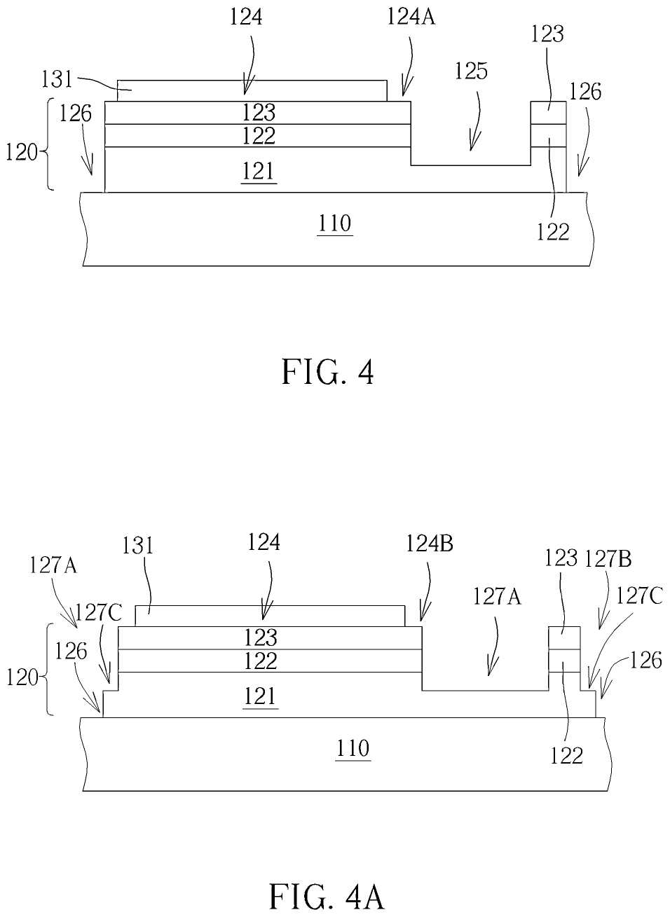

FIG. 1, FIG. 2, FIG. 3, FIG. 4, FIG. 5 and FIG. 6 illustrate schematic flowcharts of a first embodiment of a manufacturing method of a semiconductor element 101 according to the present disclosure, which illustrate schematic cross-sectional views of the semiconductor element 101. The semiconductor element 101 of the present disclosure may be applied to an electronic device, such as a display device, a bendable or flexible electronic device and/or a splicing device. It should be noted that the electronic device may be any combination of the above, but the present disclosure is not limited thereto. The electronic devices may, for example, include light-emitting diodes, such as a mini-LED, a micro-LED, an OLED, a QD-LED or a combination of the above, but the present disclosure is not limited thereto. Each embodiment of the present disclosure proposes one or more light-emitting units disposed on the substrate 110, wherein the light-emitting unit including a light-emitting diode (LED) is taken as an example in the present disclosure, but the present disclosure is not limited thereto.

First, as shown in FIG. 1, a substrate 110 is provided. The substrate 110 may be a substrate 110 of high thermal conductivity, for example, in some examples, may include sapphire (Al₂O₃), silicon (Si), silicon carbide (SiC), other known suitable materials, or a combination of the above, but the present disclosure is not limited thereto.

Next, as shown in FIG. 1, a semiconductor stack 120 is formed on the substrate 110. For example, in some examples, the semiconductor stack 120 may be formed by an epitaxial growth process, or in other examples, by metal organic chemical vapor deposition (MOCVD), but the present disclosure is not limited thereto. The semiconductor stack 120 may include a plurality of stack layers. For example, in some examples, the semiconductor stack 120 may include at least a first-type semiconductor layer 121, a multiple quantum well (MQW) layer 122 and a second-type semiconductor layer 123 sequentially stacked from the surface of the substrate 110, but the present disclosure is not limited thereto. According to some embodiments of the present disclosure, the first-type semiconductor layer 121 may be an N-type semiconductor layer, and the second-type semiconductor layer 123 may be a P-type semiconductor layer, but the present disclosure is not limited thereto. According to other embodiments of the present disclosure, the first-type semiconductor layer 121 may be a P-type semiconductor layer, and the second-type semiconductor layer 123 may be an N-type semiconductor layer, but the disclosure is not limited thereto. In other embodiments of the present disclosure, the thickness of the first-type semiconductor layer 121 may be greater than the thickness of the second-type semiconductor layer 123, but the present disclosure is not limited thereto. The thickness of the first type semiconductor layer 121 or the thickness of the second type semiconductor layer 123 may be measured along a normal direction perpendicular to the surface of the substrate 110, but the disclosure is not limited thereto.

The materials of the first type semiconductor layer 121 or the materials of the second type semiconductor layer 123 may be semiconductor compounds of Groups III-V. According to some embodiments of the present disclosure, the group III element may be an element in the Group IIIA in the periodic table of chemical elements, such as boron, aluminum, gallium, indium, and thallium, but the present disclosure is not limited thereto. The V group element may be a VA group element in the periodic table of chemical elements, such as nitrogen, phosphorus, arsenic, antimony, and bismuth, but the present disclosure is not limited thereto. The materials of the first-type semiconductor layer 121 or the materials of the second-type semiconductor layer 123 may be independently selected from semiconductor compounds formed by elements of Group III with Group V, such as gallium nitride, but the present disclosure is not limited thereto. According to some embodiments of the present disclosure, the first-type semiconductor layer 121 may include an N-type semiconductor layer, such as an N—GaN layer, and the second-type semiconductor layer 123 may include a P-type semiconductor layer, such as an P—GaN layer, but the present disclosure is not limited thereto.

Then, as shown in FIG. 2, a patterned ohmic contact layer 131 is formed on the semiconductor stack 120. According to some embodiments of the present disclosure, the ohmic contact layer 131 is beneficial to reduce the contact resistance of the first type semiconductor layer 121 or to reduce the contact resistance of the second type semiconductor layer 123, thereby helping improve the current distribution of a light-emitting diode product, or may also help improve the light-emitting efficiency of a light-emitting diode product. For example, the contact resistance between the ohmic contact layer 131 and the semiconductor stack 120 may be lower than the contact resistance between the metal electrode (not shown) and the semiconductor stack 120, which is beneficial to the uniform diffusion of the current via the ohmic contact layer 131 to the first type semiconductor layer 121 or to the second type semiconductor layer 123, thereby improving the performance of the light emitting diodes, but the present disclosure is not limited thereto.

The ohmic contact layer 131 may include a conductive material, such as a transparent conductive material. The transparent conductive material may include tin oxide, zinc oxide or indium oxide, or a combination of the above, for example, may include indium gallium zinc oxide (IGZO) or indium tin oxide (ITO), but the present disclosure is not limited thereto. According to some embodiments of the present disclosure, a sputtering method may be used to form a buck of amorphous conductive material layer on the top surface 120A of the semiconductor stack 120, such as the surface of the second-type semiconductor layer 123, to serve as an ohmic contact material layer. The sputtering thickness of the ohmic contact material layer may be between 0.3 μm and 0.6 μm (0.3 μm≤thickness≤0.6 μm), but the disclosure is not limited thereto.

After a buck of ohmic contact material layer (not shown) is formed on the semiconductor stack 120, it may be further patterned to form an ohmic contact layer 131 shown in FIG. 2, that is, a patterned ohmic contact layer 131. For example, a predetermined pattern may be formed on a buck of ohmic contact material layer (not shown) to help form various products. A buck of ohmic contact material layer may be patterned by using a conventional lithographic process. For example, in some examples, a patterned photoresist layer (not shown) which covers the ohmic contact material layer may be formed after an exposing step, a developing step and a baking step carried out on the entire ohmic contact material layer. Then, the patterned photoresist layer is used as a mask, an appropriate etching recipe is used to carry out an etching step on the entire ohmic contact material layer, to remove the ohmic contact material layer which is not covered by the patterned photoresist layer then the patterned ohmic contact layer 131 is obtained after the patterned photoresist layer residue is removed. The etching recipe of the ohmic contact layer 131 may be a strong acid composition, but the present disclosure is not limited thereto. After the etching step, the ohmic contact layer 131 which is obtained by the sputtering step is in a form of an amorphous material state.

Second, as shown in FIG. 2, an annealing process may be carried out on the ohmic contact layer 131. The annealing process may be a thermal treatment in which an object is slowly heated to a certain temperature, kept for a sufficient time, and then cooled down at a suitable rate so that the microstructure of the material of the object is changed. According to some embodiments of the present disclosure, the annealing process may change the material state of the ohmic contact layer 131, so that the material of the ohmic contact layer 131 is no longer in an amorphous material state, to become a crystallized material, which is conducive to the formation of a stable ohmic contact layer 131. According to some embodiments of the present disclosure, the ohmic contact layer 131 may include an indium tin oxide composition to serve as a transparent conductive material, but the present disclosure is not limited thereto. According to other embodiments of the present disclosure, after the annealing process is carried out, for example, the indium tin oxide composition may be densified, so that the transparent conductive material may be converted to a crystallized indium tin oxide composition, thus forming an indium tin oxide composition of stable quality. In a process flow concept provided by the present disclosure, the indium tin oxide composition may be sputtered to form a film, patterned, followed by carrying out an annealing process, so that the ohmic contact layer 131 becomes a crystallized material, which is beneficial to make the ohmic contact layer 131 resist possible damage caused by subsequent processes.

According to some embodiments of the present disclosure, the crystallized indium tin oxide composition may be manufacture by increasing the temperature at the same time, for example, in a temperature range of 300° C. to 500° C., or by adjusting appropriate process parameters, for example, in a process parameter range at a gas pressure of up to 5 mtorr, the power from 50 watts (W) to 250 watts when the conductive material film is formed. According to other embodiments of the present disclosure, first an amorphous conductive material may also be fabricated by a low-temperature sputtering method, patterned and then at a flow rate of about 5 s.c.c.m. to 10 s.c.c.m. of air (e.g. N₂80% and O₂20%), such as in a condition of N₂80% and O₂20%, to carry out a high temperature annealing process since the etching of the crystallized material requires strong acid and is likely to cause some residues to be beneficial for the ohmic contact layer 131 to become a crystallized material.

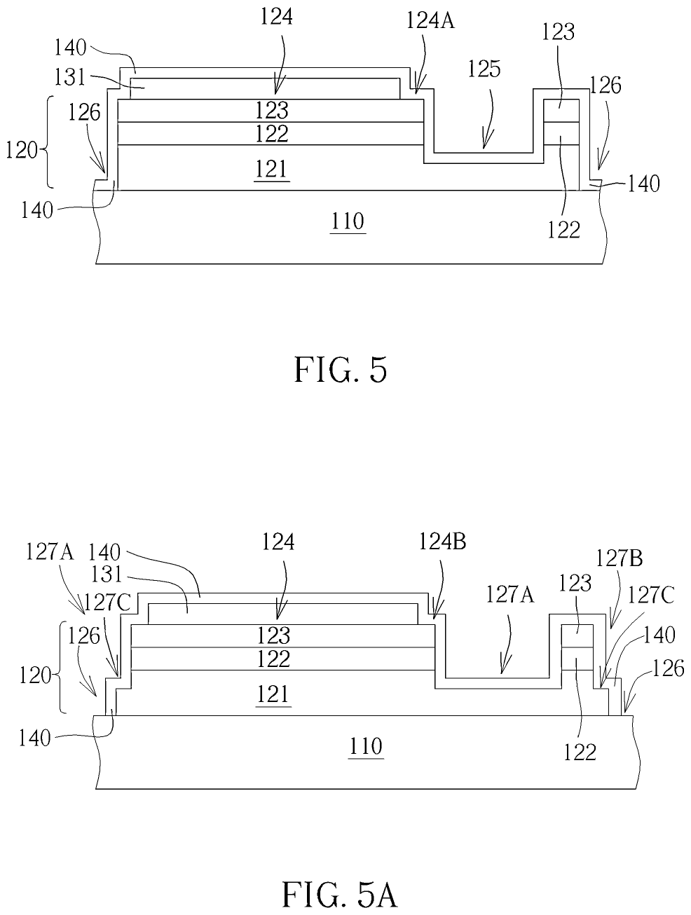

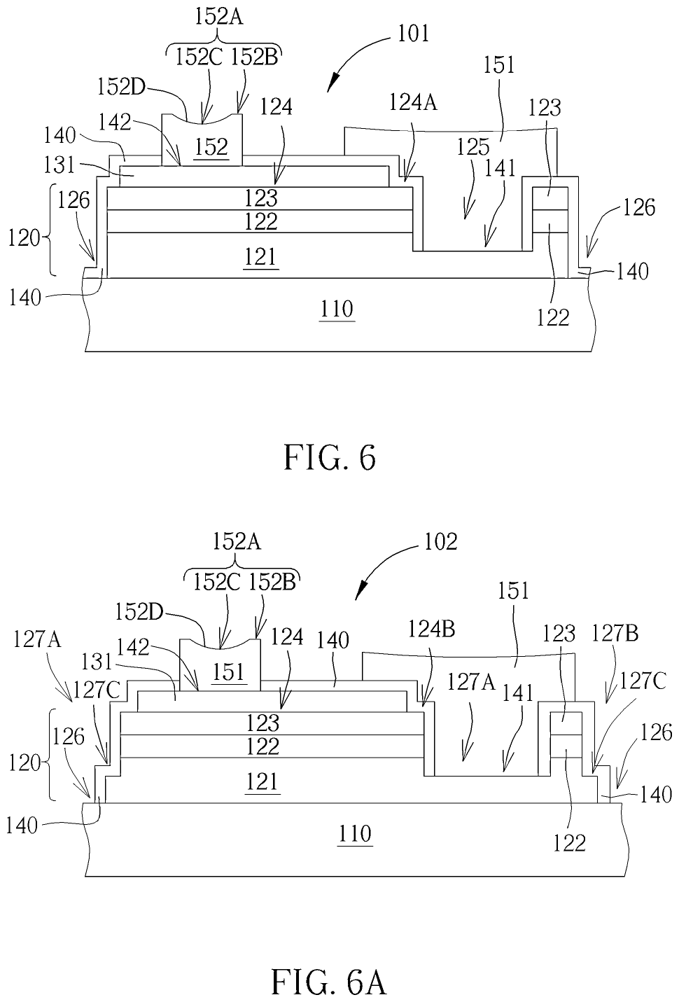

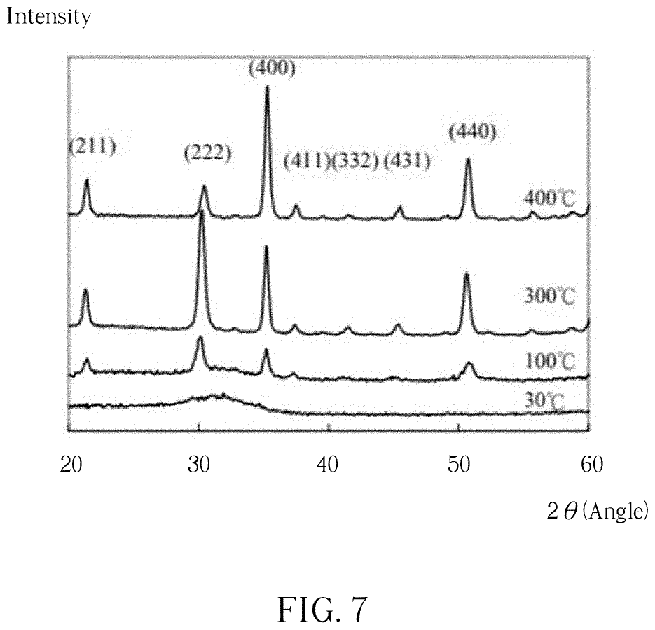

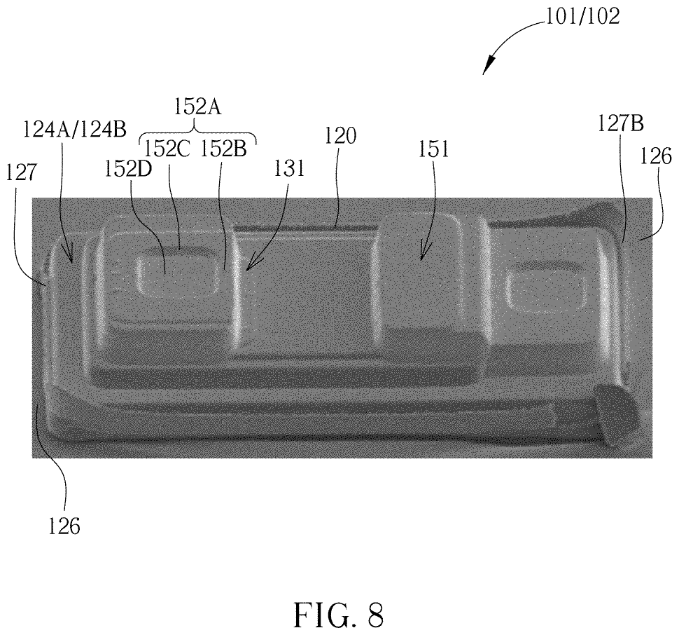

FIG. 7 shows the X-ray diffraction peak patterns of X-ray diffraction analysis (XRD) diffracted at specific angles of the indium tin oxide composition under different temperature conditions. It may be seen from the diffraction spectra peaks of 2θ angle versus different temperature conditions in FIG. 8 that the quality of the indium tin oxide composition film may tend to change from amorphous (blurred diffraction peaks) to crystalline material (obvious diffraction peaks) when the temperature increases. The lattice directions tested in the X-ray diffraction analysis may be (211), (222), (400), (411), (431), (440). Among them, crystal planes such as (211), (400), and (440) may be used as the main references. According to some embodiments of the present disclosure, the reference film of amorphous indium tin oxide composition may be prepared by a sputtering method to be compared with the unknown indium tin oxide composition sample film on (211), (400), (440) X-ray diffraction peak intensities of the crystalline planes. When the XRD diffraction peak intensity of at least one of (211), (400), and (440) of the unknown indium tin oxide composition sample film suggests an observable change, the unknown indium tin oxide composition film sample may be determined accordingly to be a crystalline (poly) thin film material.

Next, as shown in FIG. 3, after the annealing process is carried out, a mesa process may be carried out on the semiconductor stack 120 to form a platform 124 of the semiconductor element. In the mesa process, a concave 125 may be formed on the semiconductor stack 120 in a patterned manner to expose the interface between the first type semiconductor layer 121 and the second type semiconductor layer 123. The concave 125 also exposes the quantum well layer 122, the interface between the quantum well layer 122 and the first type semiconductor layer 121, and the interface between the quantum well layer 122 and the second type semiconductor layer 123. According to some embodiments of the present disclosure, the mesa process after the annealing process may include etching the semiconductor stack 120 to selectively remove some portions of the first type semiconductor layer 121, of the quantum well layer 122 and of the second type semiconductor layer 123, to form a platform 124 and a concave 125 adjacent to the platform 124 on the semiconductor stack 120. In some embodiments, the platform 124 and the concave 125 may together form the stepped structure 124A, or the ohmic contact layer 131, the platform 124 and the concave 125 may together form the stepped structure 124A, but the present disclosure is not limited thereto. The mesa process to be carried out immediately after the annealing process is beneficial to reduce potential risk of damage when each layer in the semiconductor stack 120, such as, but not limited to, the first type semiconductor layer 121, the quantum well layer 122 and the second type semiconductor layer 123, is excessively exposed to ambient conditions.

The mesa process may be carried out by using a conventional lithographic process. For example, in some examples, a patterned photoresist layer (not shown) which covers the entire semiconductor stack 120 and the ohmic contact layer 131 may be formed after an exposing step, a developing step and a baking step are carried out on the entire semiconductor stack 120 and the ohmic contact layer 131. Then, the patterned photoresist layer is used as a mask and an etching step is carried out on the entire semiconductor stack 120 by using an appropriate etching method to remove the semiconductor stack 120 which is not covered by the patterned photoresist layer and then the patterned photoresist layer residue is removed to obtain the patterned semiconductor stack 120, the corresponding platform 124 and the stepped structure 124A. At this time, the concave 125 may not expose the substrate 110. A suitable etching method may be, for example, a dry etching method which may be processed by an inductively coupled plasma (ICP) dry etching device, but the present disclosure is not limited thereto.

Then, as shown in FIG. 4, an isolation process may be optionally carried out on the semiconductor stack 120 after the mesa process is carried out on the semiconductor stack 120 to form the platform 124. According to some embodiments of the present disclosure, the isolation process carried out on the semiconductor stack 120 may allow the semiconductor stack 120 formed in the mesa process to be penetrated and to expose the substrate 110. For example, in some examples, an isolation process is carried out and a portion of the first type semiconductor layer 121 is selectively removed, so that a via 126 is formed in the semiconductor stack 120. The via 126 formed in the isolation process may further penetrate the bottom layer of the semiconductor stack 120, such as the first type semiconductor layer 121, and expose the substrate 110 under the bottom layer, and the adjacent parts of the semiconductor stack 120 are divided into a plurality of parts separated from each other by the via 126. In other embodiments, the width of the via 126 may not be greater than the width of the concave 125, but the present disclosure is not limited thereto. The width of the via 126 and the width of the concave 125 may be measured along a direction parallel to the surface of the substrate 110, but the disclosure is not limited thereto. In still another embodiments, the via 126 and the concave 125 may be independent of each other, in other words, the via 126 may not be disposed in the concave 125.

Afterwards, as shown in FIG. 5, a passivation layer 140 may be further formed after the semiconductor stack 120 is subjected to the mesa process. According to some embodiments of the present disclosure, the passivation layer 140 may be conformally formed on the ohmic contact layer 131 and on the semiconductor stack 120 to cover the ohmic contact layer 131 and the semiconductor stack 120. The passivation layer 140 may also conformally cover the platform 124 and the stepped structure 124A. The passivation layer 140 may further fill the concaves 125 and the via 126 respectively, and cover the substrate 110 which is exposed by the via 126 at the same time. In other words, according to some embodiments of the present disclosure, the passivation layer 140 may directly contact the substrate 110, the first type semiconductor layer 121, the quantum well layer 122, the second type semiconductor layer 123, the platform 124, the stepped structure 124A, and the ohmic contact layer 131 respectively. According to other embodiments of the present disclosure, the passivation layer 140 may also conformally fill the concaves 125 and the via 126 respectively. In some examples, the passivation layer 140 may be formed by using spin coating or plasma enhanced chemical vapor deposition (PECVD). In other embodiments, the passivation layer 140 may include spin-on glass oxide (SOG), silicon dioxide (SiN), aluminum oxide (Al₂O₃), hafnium oxide (HfO₂), titanium dioxide (TiO₂), boron nitride (SiN), aluminum nitride (AlN), silicon nitride (SiN), or other suitable materials, or arbitrary combinations thereof, but the present disclosure is not limited thereto.

Next, as shown in FIG. 6, after the semiconductor stack 120 is subjected to the mesa process or the passivation layer 140 is formed, the semiconductor stack 120 may be optionally subjected to some post-processing steps to obtain the semiconductor element 101. According to some embodiments of the present disclosure, the post-processing steps may include forming the first electrode 151 and the second electrode 152 separately or simultaneously. The formation of the first electrode 151 and of the second electrode 152 facilitates the connection of the first type semiconductor layer 121 or of the second type semiconductor layer 123 to external electronic components. In some examples, the first electrode 151 may be electrically connected to the first type semiconductor layer 121, for example, in direct contact, and the second electrode 152 may be electrically connected to the ohmic contact layer 131, for example, in direct contact. In other embodiments, the first electrode 151 may be electrically connected to the ohmic contact layer 131, for example, in direct contact, and the second electrode 152 may be electrically connected to the first type semiconductor 121, for example, in direct contact, but the present disclosure is not limited thereto. The first electrode 151 or the second electrode 152 may respectively include a suitable transparent conductive material or an opaque conductive material, for example, may respectively include indium tin oxide, gold (Au), silver (Ag), tin (Sn), copper (Cu), aluminum (Al), molybdenum (Mo), titanium (Ti), tantalum (Ta), niobium (Nb), hafnium (Hf), nickel (Ni), chromium (Cr), cobalt (Co), zirconium (Zr), tungsten (W), the alloys of the above, or a combination thereof, but the present disclosure is not limited thereto.

According to some embodiments of the present disclosure, the method of forming the first electrode 151 and the second electrode 152 may include first selectively removing a portion of the passivation layer 140, and then forming the first electrode 151 and the second electrode 152 of conductive materials. For example, a patterned photoresist layer (not shown) which covers the entire passivation layer 140 may be formed after an exposing step, a developing step and a baking step are carried out on the entire passivation layer 140. Then, using the patterned photoresist layer as a mask, an etching step is carried out on the entire passivation layer 140 to remove the passivation layer 140 which is not covered by the patterned photoresist layer by using an appropriate etching recipe to obtain a patterned passivation layer 140, but the present disclosure is not limited thereto. The etched passivation layer 140 may selectively expose underlying material layers. In some examples, the etched passivation layer 140 may selectively expose the first type semiconductor layer 121 disposed in the concave 125. In other examples, the etched passivation layer 140 may also selectively form an opening 141 and an opening 142. For example, the opening 141 selectively exposes the first type semiconductor layer 121 which is disposed in the concave 125, and the opening 142 selectively exposes the ohmic contact layer 131, such as a crystallized indium tin oxide composition, but the present disclosure is not limited thereto. Before the passivation layer 140 is etched, the ohmic contact layer 131 has been subjected to an annealing process and converted into a stable crystallized material, which is beneficial to reduce the possible collateral damage to the stable ohmic contact layer 131 when the passivation layer 140 is etched. This may be one of the advantages of the manufacturing method of a semiconductor element of the present disclosure.

An electrical connection step may then be carried out on the semiconductor stack 120 on the patterned passivation layer 140. For example, an electrode layer (not shown) which entirely covers the patterned passivation layer 140 may be formed on the patterned passivation layer 140. Then, after an exposing step, a developing step and a baking step are carried out on the entire electrode layer, a patterned photoresist layer (not shown) which covers the entire electrode layer is formed. Then, using the patterned photoresist layer as a mask, the entire electrode layer is etched with an appropriate etching recipe, the electrode layer which is not covered by the patterned photoresist layer is etched, and the residual patterned photoresist is stripped off (not shown) to obtain a patterned electrode layer, for example, a first electrode 151 in direct contact with the first type semiconductor layer 121 and a second electrode 152 in direct contact with the ohmic contact layer 131 may be simultaneously formed, but the present disclosure is not limited thereto.

According to some embodiments of the present disclosure, the method of forming the first electrode 151 and the second electrode 152 may include conformally forming electrodes which covers the opening 142 and the entire patterned passivation layer 140 on the entire patterned passivation layer 140. Since the position of the opening 142 is slightly lower than the surface of the passivation layer 140, the overall topology of the electrode layer which is formed on the entire uneven passivation layer 140 is affected collaterally. For example, the top surface 152A of the second electrode 152 which is in direct contact with the ohmic contact layer 131 may be recessed from a marginal portion 152B to a central portion 152C, so a recess 152D may be formed in the central portion 152C. In other words, the height of the marginal portion 152B of the top surface 152A of the second electrode 152 may be slightly higher than the height of the central portion 152C. The height of the marginal portion 152B or the height of the central portion 152C may be measured along a normal direction perpendicular to the surface of the substrate 110, but the present disclosure is not limited thereto. Since the conformality also collaterally affect the overall topology of the electrode layer formed on the entire uneven passivation layer 140, the height of the marginal portion 152B of the top surface 152A of the second electrode 152 may be different from the height of the central portion 152C so it may then be one of the features of the manufacturing method of a semiconductor element of the present disclosure.

The display device of the present disclosure is not limited to the above-mentioned embodiments. Other embodiments of the present disclosure will be described below. In order to simplify the descriptions and highlight the differences between embodiments, the same reference numerals are used to denote the same elements hereinafter, and similar descriptions are not elaborated again. In addition, the materials of each film layer or element in the subsequent embodiments may be referred to the above embodiments, so the details are not elaborated again.

FIG. 1, FIG. 2, FIG. 3A, FIG. 4A, FIG. 5A to FIG. 6A are schematic flowcharts of a second embodiment of a manufacturing method of a semiconductor element according to the present disclosure, which illustrate schematic cross-sectional views of the semiconductor element. The detailed structures and the relative relationship of the components may roughly correspond to the schematic flow charts of the first embodiment of the manufacturing method of a semiconductor element of the present disclosure, so similar descriptions are not elaborated again. The main differences between the first embodiment and the second embodiment reside in the differences between the mesa etching process and the isolation etching process.

In the process of the second embodiment of the manufacturing method of a semiconductor element of the present disclosure, the semiconductor stack 120 as shown in FIG. 2 may be provided first. The semiconductor stack 120 may include a crystallized ohmic contact layer 131 after an annealing process. Second, as shown in FIG. 3A, after the annealing process is carried out, a mesa process may be carried out on the semiconductor stack 120 to form a platform 124 of the semiconductor element. According to some embodiments of the present disclosure, the mesa process after the annealing process may include etching the semiconductor stack 120 to form a platform 124 on the semiconductor stack 120 and one or more concaves surrounding the platform 124. FIG. 3A shows the platform etching process of the second embodiment to form a concave 127A and a concave 127B, wherein the concave 127A is adjacent to the platform 124, and the concave 127B is farther away from the platform 124, that is, from a top view of the normal direction of the substrate 110, the concave 127A may be regarded as being disposed between the platform 124 and the concave 127B, but the present disclosure is not limited thereto. According to other embodiments of the present disclosure, the platform 124 and the concave 127A may together form a stepped structure 124B, or in other embodiments, the ohmic contact layer 131, the platform 124 and the concave 127A may together form the stepped structure 124B. In some embodiments, the mesa process to be carried out immediately after the annealing process is beneficial to reduce potential risk of damage when each layer in the semiconductor stack 120 is excessively exposed to ambient conditions.

Then, as shown in FIG. 4A, according to some embodiments of the present disclosure, after the semiconductor stack 120 is subjected to the mesa process, an isolation process may be optionally carried out on the semiconductor stack 120. For example, an isolation etching process may be selectively carried out on the concaves of the semiconductor stack 120, to further form vias 126 in some of the concave 127A and in the concave 127B. The via 126 may further penetrate the bottom layer, such as the first type semiconductor layer 121, of the semiconductor stack 120 in the concave 127A and in the concave 127B to expose the substrate 110 under the bottom layer, and the adjacent parts of the semiconductor stack 120 are divided into a plurality of parts separated from each other by the via 126. In some embodiments, the width of the via 126 may not be greater than the width of the concave 127A or of the concave 127B, but the present disclosure is not limited thereto. The width of the via 126 and the width of the concave 127A or of the concave 127B may be measured along a direction parallel to the surface of the substrate 110, but the disclosure is not limited thereto. In still other embodiments, the via 126 may be disposed in the concave 127A or in the concave 127B. During the isolation etching process, a laterally extending surface 127C may also be formed in the concave 127A or in the concave 127B at a position adjacent to the via 126. In other words, the isolation etching process of the second embodiment may form a structure where a concave is adjacent to the surface 127C, so it may be another feature of the manufacturing method of a semiconductor element of the present disclosure.

Next, as shown in FIG. 5A, after the semiconductor stack 120 is subjected to the mesa process, a passivation layer 140 may be further formed. According to some embodiments of the present disclosure, the passivation layer 140 may be conformally formed on the ohmic contact layer 131 and on the semiconductor stack 120 to cover the ohmic contact layer 131 and the semiconductor stack 120. The passivation layer 140 may also cover the platform 124 and the stepped structure 124B. The passivation layer 140 may further fill the via 126, the concave 127A and the concave 127B respectively, and simultaneously cover the substrate 110 which is exposed by the via 126. In other words, according to some embodiments of the present disclosure, the passivation layer 140 may directly contact the substrate 110, the first type semiconductor layer 121, the quantum well layer 122, the second type semiconductor layer 123, the platform 124, the stepped structure 124B, the ohmic contact layer 131, and the surface 127C, respectively. According to other embodiments of the present disclosure, the passivation layer 140 may also conformally fill the via 126, the concave 127A and the concave 127B, respectively.

Then, as shown in FIG. 6A, after the semiconductor stack 120 is subjected to the mesa process or the passivation layer 140 is formed, the semiconductor stack 120 may be optionally subjected to post-processing steps to obtain the semiconductor element 102. According to some embodiments of the present disclosure, the post-processing steps may include forming the first electrode 151 and the second electrode 152 separately or simultaneously. The formation of the first electrode 151 and the second electrode 152 helps the formation of external electric connection of the first type semiconductor layer 121 or of the second type semiconductor layer 123. In some examples, the first electrode 151 may be electrically connected to the first type semiconductor layer 121, for example, in direct contact, and the second electrode 152 may be electrically connected to an ohmic contact layer 131, for example, in direct contact. In other embodiments, the first electrode 151 may be electrically connected to the ohmic contact layer 131, for example, in direct contact, and the second electrode 152 may be electrically connected to the first type semiconductor layer 121, for example, in direct contact, but the present disclosure is not limited thereto. In other examples, the first electrode 151 may be disposed in the concave 127A, and there may be no electrode in the concave 127B.

According to some embodiments of the present disclosure, the method of forming the first electrode 151 and the second electrode 152 may include first selectively removing a portion of the passivation layer 140, and then forming the first electrode 151 and the second electrode 152 of conductive material. In some examples, the etched passivation layer 140 may also selectively form an opening 141 and an opening 142. For example, the opening 141 selectively exposes the first type semiconductor layer 121 which is disposed in the concave 127A. Or, the opening 142 may selectively expose the ohmic contact layer 131, such as a crystallized indium tin oxide composition, but the present disclosure is not limited thereto. Before the passivation layer 140 is etched, the stable ohmic contact layer 131 has been subjected to an annealing process and converted into a stable crystallized material, which is beneficial to reduce the possible collateral damage to the stable ohmic contact layer 131 when the passivation layer 140 is etched. This may be one of the advantages of the manufacturing method of a semiconductor element of the present disclosure.

Then, an electrical connection step may then be carried out on the semiconductor stack 120 on the entire patterned passivation layer 140 to form a first electrode 151 and a second electrode 152. According to some embodiments of the present disclosure, the method of forming the first electrode 151 and the second electrode 152 may include conformally forming electrodes (not shown) which covers the opening 142 and the entire patterned passivation layer 140 on the entire patterned passivation layer 140. Since the position of the opening 142 is slightly lower than the surface of the passivation layer 140, the overall topology of the electrode layer which is formed on the entire uneven passivation layer 140 is affected collaterally. For example, the top surface 152A of the second electrode 152 which is in direct contact with the ohmic contact layer 131 may be recessed from a marginal portion 152B to a central portion 152C, so a recess 152D may be formed in the central portion 152C. In other words, the height of the marginal portion 152B of the top surface 152A of the second electrode 152 may be slightly higher than the height of the central portion 152C. The height of the marginal portion 152B or the height of the central portion 152C may be measured along a normal direction perpendicular to the surface of the substrate 110, but the present disclosure is not limited thereto. Since the conformality also collaterally affect the overall topology of the electrode layer formed on the entire uneven passivation layer 140, the height of the marginal portion 152B of the top surface 152A of the second electrode 152 may be different from the height of the central portion 152C so it may then be one of the features of the manufacturing method of a semiconductor element of the present disclosure.

After the process of the first embodiment of the manufacturing method of a semiconductor element of the present disclosure or the process of the second embodiment of the manufacturing method of a semiconductor element of the present disclosure, the semiconductor element structures as shown in FIG. 6 or in FIG. 6A which shows a schematic cross-sectional view of a semiconductor element structure may be obtained. The semiconductor element 101 or the semiconductor element 102 of the present disclosure may at least include a first-type semiconductor layer 121, a quantum well layer 122, a second-type semiconductor layer 123, a platform 124, an ohmic contact layer 131, a passivation layer 140, a first electrode 151 and the second electrode 152.

Please refer to FIG. 6 or to FIG. 6A, the semiconductor stack 120 is disposed on the substrate 110. The substrate 110 may be a substrate 110 of high thermal conductivity, for example, in some embodiments, may include sapphire, silicon (Si), silicon carbide, other known suitable materials, or a combination thereof, but the present disclosure is not limited thereto. The semiconductor stack 120 may include a plurality of stacks. For example, the semiconductor stack 120 may at least include a first type semiconductor layer 121, a quantum well layer 122, and a second type semiconductor layer 123 sequentially stacked from the surface of the substrate 110, but the disclosure is not limited thereto. According to some embodiments of the present disclosure, the first-type semiconductor layer 121 may be an N-type semiconductor layer, and the second-type semiconductor layer 123 may be a P-type semiconductor layer, but the disclosure is not limited thereto. In other examples of the present disclosure, the thickness of the first-type semiconductor layer 121 may be greater than the thickness of the second-type semiconductor layer 123, but the present disclosure is not limited thereto. The thickness of the first type semiconductor layer 121 or the thickness of the second type semiconductor layer 123 may be measured along a normal direction perpendicular to the surface of the substrate 110, but the disclosure is not limited thereto.

In some examples, the platform 124 and the concave 125 may together form a stepped structure 124A, or in other examples, the ohmic contact layer 131, the platform 124 and the concave 125 may together form the stepped structure 124A, but the disclosure is not limited thereto. In other examples, the platform 124 and the concave 127A may together form the stepped structure 124B, or in other examples, the ohmic contact layer 131, the platform 124 and the concave 127A may together form the stepped structure 124B. The quantum well layer 122 may be disposed on the platform 124 of the first type semiconductor layer. The second type semiconductor layer 123 may be disposed on the quantum well layer 122.

The ohmic contact layer 131 may be disposed on the second type semiconductor layer 123. The ohmic contact layer 131 includes a transparent conductive material. The transparent conductive material may include tin oxide, zinc oxide or indium oxide, or a combination of the above, for example, may include indium gallium zinc oxide or indium tin oxide, but the disclosure is not limited thereto. According to some embodiments of the present disclosure, the transparent conductive material may be crystallized indium tin oxide.

The semiconductor element 101 or the semiconductor element 102 of the present disclosure may further include a passivation layer 140. The passivation layer 140 may be disposed on the ohmic contact layer 131 and on the first type semiconductor layer 121. According to some embodiments of the present disclosure, the passivation layer 140 may be conformally formed on the ohmic contact layer 131 and on the semiconductor stack 120 to cover the ohmic contact layer 131 and the semiconductor stack 120. The passivation layer 140 may also conformally cover the platform 124 and the stepped structure 124B. The passivation layer 140 may be further conformally fill the via 126, the concave 127A and the concave 127B respectively, and simultaneously cover the substrate 110 which is exposed by the via 126. In other words, according to some embodiments of the present disclosure, the passivation layer 140 may directly contact the substrate 110, the first type semiconductor layer 121, the quantum well layer 122, the second type semiconductor layer 123, the platform 124, the stepped structure 124B, the ohmic contact layer 131, the surface 127C, respectively. In some examples, the passivation layer 140 may include a first opening 141 and a second opening 142. The first electrode 151 may be electrically connected to the first type semiconductor layer 121 via the first opening 141, and the second electrode 152 may be electrically connected to the ohmic contact layer 131 via the second opening 142.

The first electrode 151 or the second electrode 152 may respectively include a suitable transparent or opaque conductive material such as indium tin oxide, gold, silver, tin, copper, aluminum, molybdenum, titanium, tantalum, niobium, hafnium, nickel, chromium, cobalt, zirconium, tungsten, the alloys of the above, or a combination thereof, but the disclosure is not limited thereto. According to some embodiments of the present disclosure, the top surface 152A of the second electrode 152 in direct contact with the ohmic contact layer 131 may be uneven. For example, the marginal portion 152B is recessed toward the central portion 152C, so the recess 152D may be formed in the central portion 152C. In other words, the height of the marginal portion 152B of the top surface 152A of the second electrode 152 may be slightly higher than the height of the central portion 152C. The height of the marginal portion 152B or the height of the central portion 152C may be measured along a normal direction perpendicular to the surface of the substrate 110, but the present disclosure is not limited thereto. The height of the marginal portion 152B of the top surface 152A of the second electrode 152 may be different from the height of the central portion 152C, which may be one of the structural features of the semiconductor element 101 or of the semiconductor element 102 of the present disclosure.

FIG. 8 shows a top-view image of a scanning electron microscope (SEM) of the semiconductor element 101 or of the semiconductor element 102 of the present disclosure. SEM images may provide high-resolution images of the surface and near-surface of the sample. As shown in FIG. 8, the semiconductor element 101 or the semiconductor element 102 may have a semiconductor stack 120 which is covered by a passivation layer 140. The first electrode 151 and the second electrode 152 are not covered by the passivation layer 140 and are exposed. The second electrode 152 roughly covers the ohmic contact layer 131.

A via 126 or a concave 127B which is formed by an isolation etching process may be seen on the sides of the semiconductor element 101 or of the semiconductor element 102. The stepped structure 124A, the stepped structure 124B, or the surface 127C may be seen adjacent to the via 126. The top surface 152A of the second electrode 152 is recessed from the marginal portion 152B to the central portion 152C to form a recess 152D in the central portion 152C. That is, the height of the marginal portion 152B of the top surface 152A of the second electrode 152 is slightly higher than the height of the central portion 152C. The height of the marginal portion 152B of the top surface 152A of the second electrode 152 may be different from the height of the central portion 152C to form the recess 152D, which may be one of the structural features of the manufacturing method of the semiconductor element 101 or of the semiconductor element 102 of the present disclosure.

The first embodiment of the present disclosure provides a process flow concept to firstly sputter the indium tin oxide composition to form a film, to form a pattern then carry out an annealing process, so that the ohmic contact layer 131 becomes a crystallized material. After the mesa etching process, an isolation process is carried out to form a passivation layer 140 to protect the semiconductor stack 120. An electrical connection step is then carried out on the semiconductor stack 120 after the passivation layer 140 is formed. In this way, the ohmic contact layer 131 is applied first and then the ohmic contact layer 131 is converted to a crystallized material, which may prevent the subsequent etching processes of each semiconductor layer from affecting the quality of the ohmic contact layer 131. In addition, after the mesa etching process and the isolation etching process, the formation of the passivation layer 140 may protect the quality of each stack layer, which is beneficial to reduce the time that the quantum well layer 122 is exposed to ambient conditions, so it may be another features of the manufacturing method of a semiconductor element of the present disclosure.

The second embodiment of the present disclosure provides a process flow concept to firstly sputter the indium tin oxide composition to form a film, to form a pattern then carry out an annealing process, so that the ohmic contact layer 131 becomes a crystallized material. After the mesa etching process, an isolation process is carried out to form a passivation layer 140 to protect the semiconductor stack 120. An electrical connection step is then carried out on the semiconductor stack 120 after the passivation layer 140 is formed. In this way, the ohmic contact layer 131 is first applied and then the ohmic contact layer 131 is converted to a crystallized material, which may prevent the subsequent etching processes of each semiconductor layer from affecting the quality of the ohmic contact layer 131. In addition, during the mesa etching process, the concave 127A and the concave 127B may be etched to the same depth. The isolation etching process may only etch the first-type semiconductor layer 121 under the protection of the patterned photoresist layer (not shown), which is beneficial to reduce the lateral etching damage that may occur during the isolation etching process, and may reduce the impact on the quantum well layer 122, and help maintain the quality of the quantum well layer 122. The annealing process combined with the two-step platform etching process and isolation etching process may reduce the time that the quantum well layer 122 is exposed to ambient conditions and help maintain the quality of the quantum well layer 122. These advantages may be some of the features of the manufacturing method of a semiconductor element of the present disclosure.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of a semiconductor element, comprising:
providing a substrate;
forming a semiconductor stack on the substrate;
forming an ohmic contact layer on the semiconductor stack;
performing an annealing process on the ohmic contact layer; and
performing a mesa process on the semiconductor stack after performing the annealing process.

2. The manufacturing method of the semiconductor element of claim 1, further comprising:
performing an isolation process on the semiconductor stack so that the semiconductor stack is divided into a plurality of separated parts.

3. The manufacturing method of the semiconductor element of claim 1, further comprising:
forming a passivation layer on the ohmic contact layer and on the semiconductor stack.

4. The manufacturing method of the semiconductor element of claim 1, wherein the mesa process comprises etching the semiconductor stack to form a platform and a concave surrounding the platform on the semiconductor stack, and the platform and the concave together form a stepped structure.

5. The manufacturing method of the semiconductor element of claim 4, further comprising:
performing an isolation process on the semiconductor stack so that the concave of the semiconductor stack is penetrated to divide the semiconductor stack into a plurality of separated parts.

6. The manufacturing method of the semiconductor element of claim 1, wherein the semiconductor stack comprises a first-type semiconductor layer, a quantum well layer, and a second-type semiconductor layer stacked sequentially.

7. The manufacturing method of the semiconductor element of claim 6, wherein the first-type semiconductor layer is an N-type semiconductor layer.

8. The manufacturing method of the semiconductor element of claim 7, wherein the second-type semiconductor layer is a P-type semiconductor layer.

9. The manufacturing method of the semiconductor element of claim 1, wherein the ohmic contact layer comprises a transparent conductive material.

10. The manufacturing method of the semiconductor element of claim 9, wherein the transparent conductive material is a crystallized indium tin oxide.

11. A semiconductor element, comprising:
a first-type semiconductor layer, comprising a platform and a concave surrounding the platform, wherein the platform and the concave together form a stepped structure;
a quantum well layer disposed on the platform of the first-type semiconductor layer;
a second-type semiconductor layer disposed on the quantum well layer;
an ohmic contact layer disposed on the second type semiconductor layer;
a first electrode electrically connected to the first type semiconductor layer; and
a second electrode electrically connected to the ohmic contact layer.

12. The semiconductor element of claim 11, wherein the first-type semiconductor layer is an N-type semiconductor layer.

13. The semiconductor element of claim 12, wherein the second-type semiconductor layer is a P-type semiconductor layer.

14. The semiconductor element of claim 11, further comprising:
a passivation layer disposed on the ohmic contact layer and on the first-type semiconductor layer, the passivation layer comprising a first opening and a second opening, wherein the first electrode electrically connected to the first-type semiconductor layer via the first opening and the second electrode is electrically connected to the ohmic contact layer via the second opening.

15. The semiconductor element of claim 11, wherein the ohmic contact layer comprises a transparent conductive material.

16. The semiconductor element of claim 15, wherein the transparent conductive material is a crystallized indium tin oxide.

17. The semiconductor element of claim 11, wherein the second electrode has a marginal portion and a central portion.

18. The semiconductor element of claim 17, wherein a top surface of the second electrode is recessed from the marginal portion to the central portion.

19. The semiconductor element of claim 18, wherein a recess is in the central portion.

20. The semiconductor element of claim 17, wherein a height of the marginal portion is different from a height of the central portion.
